(19) United States
(12) Patent Application Publication
(10) Pub. No.: US 2022/0082513 A1
(43) Pub. Date: Mar. 17, 2022

(54) TESTING DEVICE FOR DETERMINING A DIELECTRIC VALUE

(71) Applicant: Endress+Hauser SE+Co. KG, Maulburg (DE)

(72) Inventor: Thomas Blödt, Steinen (DE)

(21) Appl. No.: 17/425,385

(22) PCT Filed: Dec. 10, 2019
(86) PCT No.: PCT/EP2019/084412

§ 371 Date: Jul. 23, 2021

(30) Foreign Application Priority Data
Jan. 23, 2019 (DE) 10 2019 101 598.7

(51) Int. Cl. G01N 22/00; G01R 27/26

(52) U.S. Cl. CPC G01N 22/00; G01R 27/2623

(57) ABSTRACT

Disclosed is to a measuring device for determining a dielectric value of a fill substance, as well as to a method for its operation. The underpinning idea is based on transmitting a high frequency signal as radar signal in the direction of the fill substance, and receiving the radar signal after passage through the fill substance. A phase detector of the receiving unit of the measuring device produces a first evaluation signal, which changes proportionally to a phase difference between the received radar signal and the produced high frequency signal. An evaluation circuit of the receiving unit determines based on the first evaluation signal at least a real part of the dielectric value. Advantageous in the case of such dielectric value determination is that the measuring device can be applied without having first to be calibrated.

The invention relates to a testing device in the form of a measuring device for determining a dielectric value of a fill substance as well as to a corresponding method for operating the measuring device.

In automation technology, especially in process automation technology, field devices are often applied, which serve for registering and/or for influencing process variables. For registering process variables, sensors are applied, which are used, for example, in fill level measuring devices, flow measuring devices, pressure- and temperature measuring devices, pH-redox potential measuring devices, conductivity measuring devices, etc. These register the corresponding process variables, such as fill level, flow, pressure, temperature, pH value, redox potential, conductivity and dielectric value. A large number of these field devices are produced and sold by the firm, Endress+Hauser.

The determination of dielectric value (also known as “dielectric constant” or “relative permittivity”) of fill substances in containers is of great interest both in the case of solids, as well as also in the case of liquid fill substances, such as, for example, fuels, waste waters or chemicals, since this value can be a reliable indicator of impurities, moisture content and substance composition. The terminology, “container”, within the scope of the invention refers also to open containers, such as, for example, vats, lakes, oceans and flowing bodies of water.

In order to determine the dielectric value according to the state of the art, above all, in the case of liquid fill substances, the capacitive measuring principle can be used. In such case, the effect is utilized that the capacitance of a capacitor changes in proportion with the dielectric value of the medium, which lies between the two electrodes of the capacitor.

Alternatively, it is also possible to co-determine the dielectric value of a (liquid) medium in a container interior virtually parasitically in radar-based fill level measurement. This requires the measuring principle of guided radar, in the case of which microwaves are guided in the medium via an electrically conductive waveguide. Such combined fill level- and dielectric measuring is described in disclosure DE 10 2015 117 205 A1.

As a rule, the measuring device is calibrated on-site in a process installation, in order to take the installed situation into consideration. On the one hand, this means an extra effort at installation. On the other hand, the measuring device, or the corresponding sensor system, is, however, often arranged in closed containers. Therefore, the creating of a defined calibration state, such as the provision of a calibration medium having defined dielectric value, is, at least in these cases, not even possible.

An object of the invention, therefore, is to provide a measuring device, which does not require calibration.

The invention achieves this object by a measuring device for determining a dielectric value of a fill substance. For this, the measuring device includes:
a signal production unit, having
   a high frequency oscillatory circuit, which is designed to produce an electrical, high frequency signal,
   a transmitting antenna, which is designed to transmit the high frequency signal as radar signal in the direction of the fill substance, and
a receiving unit, having
   a receiving antenna, which is configured to receive the radar signal after passage through the fill substance, and
   an evaluation circuit, which is designed to determine the dielectric value based on a phase difference or a signal strength of the received radar signal.

The terminology, “unit”, in the context of invention, means, in principle, every electronic circuit, which is suitably designed for the contemplated application. It can thus, depending on requirements, be an analog circuit for producing, or processing, appropriate analog signals. It can also be a digital circuit, such as an FPGA or a storage medium in cooperation with a program. In such case, the program is designed to perform the corresponding method steps, or to apply the necessary calculational operations of the pertinent unit. In this context, different electronic units of the fill level measuring device can in the sense of invention potentially also use a shared physical memory, or be operated by means of the same physical, digital circuit.

The manner of functioning of the measuring device rests according to the invention on determining the dielectric value at least in the form of a real value, in that the phase difference of the radar signal is measured between transmission and receipt. Such can be associated with the dielectric value of the fill substance without calibration, since the phase difference of the received radar signal is ascertained with reference to the signal production unit. For this, the receiving unit can comprise a phase detector, which is designed to produce a first evaluation signal, which changes proportionally to a phase difference between the received radar signal and the high frequency signal. Correspondingly, the signal production unit includes a signal divider, by means of which the high frequency signal can be coupled out of the signal production unit. Accordingly, one of the inputs of the phase detector can be connected to the signal divider for producing the evaluation signal. In this way, the evaluation circuit can determine at least a real part of the dielectric value based on the first evaluation signal.

The evaluation circuit can, moreover, be designed, supplementally or alternatively to the real part, to determine an imaginary part of the dielectric value, when the receiving unit includes an amplitude detector for registering the signal strength of the received radar signal. In such case, the amplitude detector is to be so construed that it produces the second evaluation signal as a function of signal strength of the received radar signal. The second evaluation signal can be an analog signal or an appropriately coded digital signal.

In such case, the evaluation circuit can determine the imaginary part directly from the second evaluation signal. The determination can, however, also occur indirectly, in that the amplitude detector includes at least a first controllable receiving amplifier, which produces the second evaluation signal by means of amplification of the received radar signal. The evaluation circuit is, in such case, then to be so constructed that it controls the amplification of the receiving amplifier in such a manner by means of a control signal that the second evaluation signal is approximately constant. Thus, the evaluation circuit can determine the imaginary part of the dielectric value from the second control signal.

The dynamic range of the dielectric value measuring can be increased further, when in parallel or in series with the first receiving amplifier at least a second receiving amplifier is arranged, which analogously to the first receiving amplifier produces the second evaluation signal by means of amplification of the received radar signal.

For adjusting the transmitting power of the radar signal, the signal production unit can include at least one transmission amplifier, which appropriately amplifies the high frequency signal of the high frequency oscillatory circuit. In such case, the first transmission amplifier can be controllable in such a manner that amplification of the first transmission amplifier is controllable by means of the control signal of the evaluation circuit. In this way, a high dynamic range can be covered, this being especially advantageous in the measuring of greatly attenuating fill substances.

In order to be able to determine the quality of the measuring device, or in order to prevent negative disturbance signals, the signal production unit can include a delay element, which is designed to delay the high frequency signal by a defined phase.

In order to determine the quality, the delay element is to be so constructed that it can be turned on by means of a control signal. Correspondingly for this, the receiving unit is to be so constructed that it can determine from the second evaluation signal a quality of the measuring device after turn on of the delay element. In this way, the effect is utilized that the amplitude of the received radar signal exponentially decreases during the delay, wherein the evaluation circuit can calculate the quality based on the time constant. During a quality measurement, it is necessary that the transmission amplifier be settable to a constant amplification factor by means of the control signal, in order not to influence the amplitude of the received radar signal.

For suppressing negative disturbance signals, the delay element can be designed to control the phase in such a manner that the signal strength of the received radar signal at the amplitude detector exceeds a predefined limit value. The phase is, thus, controlled in such a manner that the amplitude of the received radar signal has no minimum caused by possible negative interference.

The frequency of the radar signal is to be fitted roughly to the type of fill substance, or to the measuring range for the dielectric value. In general, it is in this connection advantageous that the high frequency oscillatory circuit be designed to produce the high frequency signal with a constant frequency between 1 GHz and 30 GHz.

Analogously to the measuring device of the invention, the object of the invention is additionally achieved by a method for determining the dielectric value by means of the measuring device according to one of the above described embodiments, wherein the method includes method steps as follows:
producing an electrical, high frequency signal by means of a high frequency oscillatory circuit,
transmitting the high frequency signal as radar signal in the direction of the fill substance by means of a transmitting antenna,
receiving the radar signal after passage through the fill substance by means of a receiving antenna,
producing by means of a phase detector a first evaluation signal, which changes proportionally to a phase difference between the received radar signal and the out-coupled high frequency signal,
determining by an evaluating unit a real part of the dielectric value based on the first evaluation signal.

In order to determine the imaginary part of the dielectric value, the method can be supplemented with method steps as follows:
producing by means of an amplitude detector a second evaluation signal dependent on signal strength of the received radar signal, and
determining an imaginary part of the dielectric value from the second evaluation signal by the evaluating unit.

When the measuring device is designed to measure the quality, the method can be so supplemented that the ability to function can be monitored (also known as “predictive maintenance”).

In such case, the method is supplemented by method steps as follows:
determining a quality of the measuring device from the second evaluation signal, and
classifying the measuring device as non-functional, when the quality subceeds a predefined minimum value.

The invention will now be explained in greater detail based on the appended drawing. The figures of the drawing show as follows:

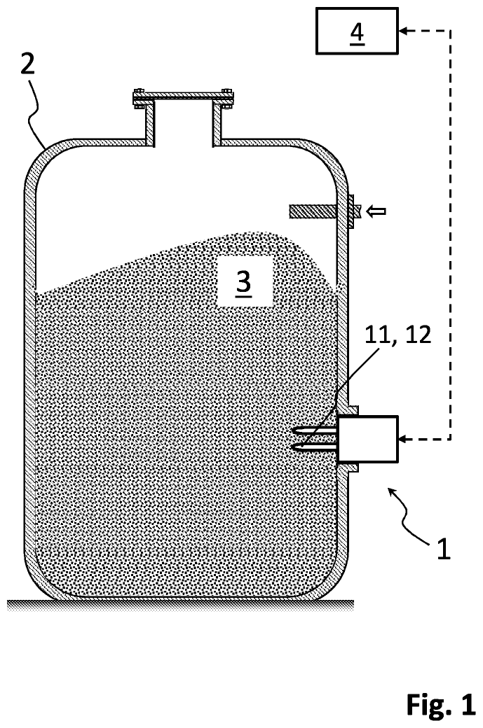

FIG. 1 a measuring device of the invention for dielectric value measuring of a fill substance in a container,

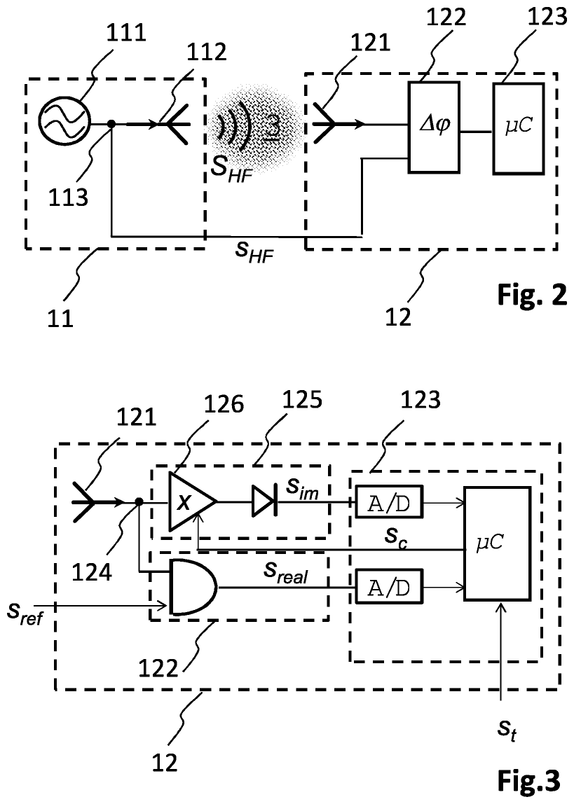

FIG. 2 a schematic construction of the measuring device of the invention,

FIG. 3 an embodiment of the receiving unit of the measuring device, and

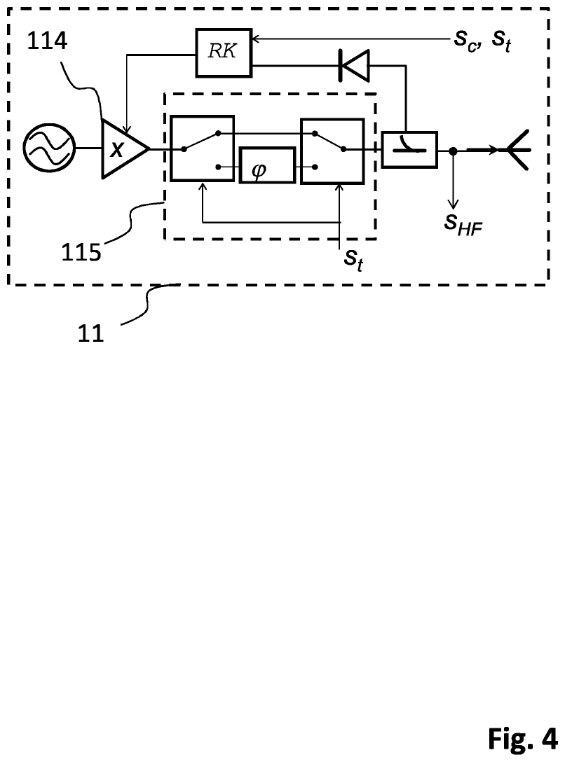

FIG. 4 an embodiment of the signal production unit of the measuring device.

For providing a general understanding of the dielectric value measuring device 1 of the invention, FIG. 1 shows a schematic arrangement of the measuring device 1 on a container 2 containing a fill substance 3. In order to determine the dielectric value DK of the fill substance 3, the measuring device 1 is arranged laterally in a port of the container 2, for example, a flanged port. For this, the measuring device 1 is mounted basically flushly with the container inner wall. The measuring device 1 for determining the dielectric value DK includes a signal production unit 11 and a receiving unit 12, which, depending on design, can extend, at least partially, into the container interior. The fill substance 3 can be liquid, such as drinks, paints, or fuels, such as liquified gases, or mineral oils. Another option is, however, also the application of the measuring device 1 for bulk good type fill substances 3, such as, for example, cement or food, or feed, grains.

The measuring device 1 can be connected to a superordinated unit 4, for example, a process control system. Provided as interface can be, for instance, a “PROFIBUS”, “HART”, “wireless HART” or “Ethernet” interface. In this way, the dielectric value DK can be transmitted as a magnitude, or as a complex value with real part and imaginary part. Also other information with reference to the general operating condition of the measuring device 1 can be communicated.

The circuit construction, in principle, of the measuring device 1 of the invention is shown in FIG. 2. Fundamentally, the measuring device 1 is based on a signal production unit 11, which serves for radiation of a radar signal S_{HF} into fill substance 2, as well as a receiving unit 12 for receiving the radar signal S_{HF}, after it has penetrated the fill substance 3. For this, the signal production unit 11 includes a transmitting antenna 112, which is driven by a high frequency oscillatory circuit 111 with an electrical, high frequency signal s_{HF}. For generating the radar signal S_{HF}, the high frequency signal s_{HF} has in such case a preferably constant frequency in the range 0.1 GHz to 240 GHz. Accordingly, the high frequency oscillatory circuit 111 can in the simplest case be designed as a quartz oscillator, which, in given cases, uses harmonic out-coupling. In addition, also a Gunn diode or a semiconductor oscillator could be applied.

The transmitting antenna 112 and the corresponding receiving antenna 121 of the receiving unit 12 have to be matched to the frequency of the radar signal S_{HF}, or the high frequency signal s_{HF}, as the case may be. Thus, the antennas 112, 121 can, for example, be planar patch antennas with appropriate edge lengths. In the case of designing the antennas 112, 121 as planar antennas, the measuring device 1 can be so designed that it terminates planarly with the inner wall of the container 2. A non-planar design of the measuring device 1, in the case of which at least the antennas 112, 121 extend into the inner space of the container 2, offers, in turn, the advantage that the antennas 112, 121 can be aligned relative to one another. This increases the resolution of the measuring.

According to the invention, the dielectric value DK of the fill substance 3 is determined by measuring the radar signal S_{HF} phase difference Δφ, which occurs between the antennas 112, 121 upon passage of the signal through the fill substance 3. For this, the receiving unit 12 includes a phase detector 122, whose one input is connected to the receiving antenna 121. The phase detector 122 can be designed, for example, as a high frequency mixer or as a Gilbert cell, which is operated below saturation.

The second input of the phase detector 122 taps the high frequency signal s_{HF} in the signal production unit 11 between the high frequency oscillatory circuit 111 and the transmitting antenna 112. To this end, the signal production unit 11 includes a corresponding signal divider 113. In such case, the signal divider 113 can be, for example, especially an asymmetric power divider. Thus, the phase detector 122 compares the phase difference Δφ before transmission and upon receipt of the radar signal S_{HF}. Accordingly, the output signal sᵣₑₐₗ of the phase detector 122 in the case of design as mixer represents the phase difference Δφ in the form of an analog voltage value.

As evident from FIG. 3, the analog output signal sᵣₑₐₗ of the phase detector 122 can in the case of design as mixer or Gilbert cell be subjected to an analog/digital conversion, so that an evaluation circuit 123, for example, a microcontroller, can determine the dielectric value DK based on the digitized signal sᵣₑₐₗ. In such case, the calculating of the real part Re_{DK} of the dielectric value DK is based on the relationship

Re_{DK}˜Δφ

Because the phase difference Δφ is determined directly based on the phase of the high frequency signal s_{HF} at the high frequency oscillatory circuit 111, the dielectric value DK, or the real part Re_{DK}, can be measured without first calibrating the measuring device 1 on the container 2.

With the embodiment of the receiving unit 12 shown in FIG. 3, it is, additionally, possible to determine besides the real part Re_{DK} of the dielectric value DK also its imaginary part Im_{DK}. For this, the radar signal s_{HF} upon receipt by the receiving antenna 121 is split via a power divider 124 and fed to the input of a receiving amplifier 126 as part of an amplitude detector 125. In principle, this form of embodiment of the receiving unit 123 utilizes for determining the imaginary part Im_{DK} the effect that the imaginary part Im_{DK} is proportional to the amplitude of the received radar signal S_{HF}. In the case of the embodiment shown in FIG. 3, the amplitude of the received radar signal S_{HF} is, however, not directly measured for determining the imaginary part Im_{DK}. Rather, the evaluation circuit 123 controls the amplification factor of the receiving amplifier 126 by means of a corresponding control signal s_{c} such that the output signal sᵢₘ of the receiving amplifier 126 is, for instance, kept constant. Due to this form of control, the control signal s_{c} delivers the actual information with reference to amplitude of the received radar signal S_{HF}, So that the evaluation circuit 123 can determine the imaginary part Im_{DK} of the dielectric value DK based on the current value of the control signal s_{c}. Since the microcontroller of the evaluation circuit 123 has in this case no analog input, FIG. 3 shows an analog/digital converter connected after the receiving amplifier 126. The measuring of the imaginary part Im_{DK} of the dielectric value DK by means of the control signal s_{c} offers the advantage that, in turn, the dynamic range of the dielectric value measuring is increased. An HF detector in the form of a diode can, such as shown in FIG. 3, follow the receiving amplifier 126, in order to be able to ascertain signal strength as a function of temperature. For this, the microcontroller can form a quotient of the first evaluation signal sᵣₑₐₗ to the second evaluation signal sᵢₘ.

The dynamic range of the measuring device 1 can be further increased, when other amplifiers are arranged in parallel or series with the receiving amplifier 126, in order to produce the second evaluation signal sᵢₘ likewise by means of amplification of the received radar signal S_{HF}. This is not shown in FIG. 3. The possible additional amplifiers can be controlled analogously to the receiving amplifier 126. Instead of the control of the receiving amplifier 126 and the determining of the imaginary part Im_{DK} based on the control signal, it is for the purpose of simpler design alternatively also an option not to control the receiving amplifier 126 and to determine the imaginary part Im_{DK} directly based on the evaluation signal sᵢₘ, thus, the output signal of the receiving amplifier 126.

FIG. 4 shows a possible further development of the signal production unit 11, with which the quality of the measuring device 1 can be measured, or monitored. In such case, quality in the context of the invention concerns the definition, bandwidth per center frequency.

For its determination, a delay element 115 is interposed between the high frequency oscillatory circuit 111 and the transmitting antenna 112. Essentially, the delay element 115 is composed of two signal splitters, between which, in one case, a direct signal path of the high frequency signal s_{HF} extends. In the other case, there is arranged between the signal splitters a delay signal path, which delays the high frequency signal s_{HF} by a defined phase 9. A delay signal path can be implemented, for example, as described in DE102012106938 A1.

The signal splitters of the delay unit 115 are, in such case, so designed that the high frequency signal s_{HF} in the case of presence of control signal sₜ travels via of the delay signal path, while the high frequency signal s_{HF} otherwise travels via the direct signal path. In such case, the front signal splitter can be designed, for example, as a Wilkinson power divider, which is followed in each signal path by an amplifier. Depending on whether the delay-, or the no-delay path should be conducting, the amplification of the corresponding amplifier is on set to infinity, while the other amplification factor is correspondingly set to zero.

The switching from the direct to the delay signal path can also be reported to the evaluation circuit 123 in the receiving unit 12 by the control signal sₜ, in that, for example, the control signal sₜ is applied simultaneously also to an input of the microcontroller. In this way, the evaluation circuit 123 can be told the point in time of the delay, so that the evaluation circuit 123 can detect a corresponding change of the second evaluation signal sᵢₘ as a result of the switching of the delay unit 115.

Since in the case of an analog second evaluation signal sᵢₘ an abrupt delay of the phase p of the high frequency signal s_{HF} leads to an exponential decline of the amplitude, the evaluation circuit can determine the quality of the measuring device 1 based on the corresponding time constant. In such case, the measuring device 1 can be so further developed that upon subceeding a predefined minimum quality it classifies itself as unable to function and, in given cases, transmits notice of this failure state to the superordinated unit 4. A reduction of quality can be brought about, on the one hand, by aging of internal electronic components. On the other hand, the quality can, however, also be decreased by a reduced transmission of the radar signal S_{HF} between the antennas 112, 121 due to accretion formation.

When also the signal-production unit 11 has a transmission amplifier 114, this must be so designed that the transmission amplifier 114 during the determining of the quality of the high frequency signal S_{HF} amplifies with a constant amplification, in order that the amplitude measurement of the second evaluation signal sᵢₘ is not superimposed therewith. To this end, the transmission amplifier 114 can, in turn, be correspondingly controlled by means of the control signal sₜ. Alternatively, the transmission amplifier 114 can be told the arising delay also in such a manner by means of the high frequency signal s_{HF} that a separate control loop RK, such as shown in FIG. 4, detects the arising delay based on the tapped high frequency signal and keeps the amplification of the transmission amplifier 114 constant in this case. Furthermore, the control loop RK can, for example, be so implemented that, when no phase delay φ is detected, the transmission amplifier 114 is controlled by means of that control signal rₜ, with which also the receiving amplifier 126 is controlled. In this way, the dynamic range, within which the measuring device 1 can determine the dielectric value DK, is increased.

Alternatively or supplementally to determining the quality, the phase delay p, which can be set by means of the delay element 115, can also be applied, in order to prevent negative interference of the radar signal S_{HF} in the case of passage through the fill substance 3. In such case, the phase delay 9 is to be so set that the amplitude of the received radar signal S_{HF}, or the second evaluation signal, has no interference related minimum, but, instead, exceeds a defined limit value. Since the amplitude is detectable by the evaluation circuit 123, also a corresponding control of the delay element 115 by the evaluation circuit 123 can occur.

### LIST OF REFERENCE CHARACTERS

1 measuring device
2 container
3 fill substance
4 superordinated unit
11 signal production unit
12 receiving unit
111 high frequency oscillatory circuit
112 transmitting antenna
113 signal divider
114 transmission amplifier
115 delay element
121 receiving antenna
122 phase detector
123 evaluation circuit
124 power divider
125 amplitude detector
126 receiving amplifier
DK dielectric value
Im_{DK} imaginary part of the dielectric value
Re_{DK} real part of the dielectric value
S_{HF} radar signal
s_{C} control signal
sᵢₘ second evaluation signal
sᵣₑₐₗ first evaluation signal
sₜ control signal
s_{HF} high frequency signal
x amplification factor
φ phase
Δφ phase difference

1-16. (canceled)

17. A measuring device for determining a dielectric value of a fill substance, comprising:
a signal production unit, including:
a high frequency oscillatory circuit designed to produce an electrical, high frequency signal; and
a transmitting antenna designed to transmit the high frequency signal as a radar signal in a direction of the fill substance; and
a receiving unit, including:
a receiving antenna configured to receive the radar signal after passage through the fill substance; and
an evaluation circuit designed to determine the dielectric value based on a phase difference or a signal strength of the received radar signal.

18. The measuring device as claimed in claim 17,
wherein the receiving unit further includes a phase detector designed to produce a first evaluation signal that changes proportionally to the phase difference between the received radar signal and the high frequency signal,
wherein the signal production unit further includes a signal divider by means of which the high frequency signal can be coupled out,
wherein the phase detector is connected to the signal divider for producing the first evaluation signal, and
wherein the evaluation circuit is designed, to determine a real part of the dielectric value based on the first evaluation signal.

19. The measuring device as claimed in claim 18, wherein the receiving unit further includes an amplitude detector that produces a second evaluation signal dependent on a signal strength of the received radar signal.

20. The measuring device as claimed in claim 19, wherein the evaluation circuit is further designed to determine an imaginary part of the dielectric value by means of the second evaluation signal.

21. The measuring device as claimed in claim 20,
wherein the amplitude detector includes a first controllable receiving amplifier designed to produce the second evaluation signal by means of amplification of the received radar signal,
wherein the evaluation circuit is further designed to control amplification of the first receiving amplifier by a control signal such that the second evaluation signal is constant, and
wherein the evaluation circuit is further designed to determine the imaginary part of the dielectric value from the control signal.

22. The measuring device as claimed in claim 21, further comprising:
a second receiving amplifier arranged in parallel or in series with the first receiving amplifier to produce the second evaluation signal by means of amplification of the received radar signal.

23. The measuring device as claimed in claim 21, wherein the signal production unit further includes a transmission amplifier that amplifies the high frequency signal.

24. The measuring device as claimed in claim 23, wherein the transmission amplifier is controllable such that amplification of the transmission amplifier is controllable by means of the control signal of the evaluation circuit.

25. The measuring device as claimed in claim 23, wherein the signal production unit further includes a delay element designed to delay the high frequency signal by a defined phase.

26. The measuring device as claimed in claim 25, wherein the delay element can be turned on by means of an additional control signal, and wherein the receiving unit is designed to determine from the second evaluation signal a quality of the measuring device after turn on of the delay element.

27. The measuring device as claimed in claim 26, wherein the transmission amplifier is settable to a constant amplification factor by means of the additional control signal.

28. The measuring device as claimed in claim 25, wherein the delay element is designed to set a phase delay such that the signal strength of the received radar signal is maximum at the amplitude detector.

29. The measuring device as claimed in claim 17, wherein the high frequency oscillatory circuit is designed to produce the high frequency signal with a constant frequency between 2 GHz and 30 GHz.

30. A method for determining a dielectric value of a fill substance, the method comprising:
producing an electrical, high frequency signal by means of a high frequency oscillatory circuit;
transmitting the high frequency signal as a radar signal in a direction of the fill substance by means of a transmitting antenna;
receiving the radar signal via a receiving antenna after passage of the radar signal through the fill substance;
producing by means of a phase detector a first evaluation signal that changes proportionally to a phase difference between the received radar signal and the out-coupled high frequency signal; and
determining by an evaluating unit a real part of the dielectric value based on the first evaluation signal.

31. The method as claimed in claim 30, further comprising:
producing by means of an amplitude detector a second evaluation signal dependent on signal strength of the received radar signal; and
determining an imaginary part of the dielectric value from the second evaluation signal by the evaluating unit.

32. The method as claimed in claim 31, further comprising:
determining a quality of the measuring device from the second evaluation signal; and
classifying the measuring device as non-functional when the quality subceeds a predefined minimum value.
